(19) United States
(12) Patent Application Publication
(10) Pub. No.: US 2026/0367204 A1
(43) Pub. Date: Nov. 19, 2026

(54) ESTIMATION ALGORITHM FOR ESTIMATING STATUS DATA OF A MAGNETIC RESONANCE SYSTEM

(71) Applicant: Siemens Healthineers AG, Forchheim (DE)

(72) Inventors: Christopher Ströhlein, Nürnberg (DE); Bruno Pinho Meneses, Witney (GB); Nicholas Aley, Maldon (GB)

(21) Appl. No.: 19/673,198

(22) Filed: May 11, 2026

(30) Foreign Application Priority Data
May 13, 2025 (DE) 10 2025 118 376.7

(51) Int. Cl. G01R 33/54; G01R 33/34; G01R 33/385

(52) U.S. Cl. CPC G01R 33/543; G01R 33/34023; G01R 33/385

(57) ABSTRACT

Systems and methods for adjustment of at least one model parameter for an estimation algorithm for estimation of status data of a magnetic resonance system. The magnetic resonance system includes a basic magnet that is arranged in a housing structure. The basic magnet and/or the housing structure are able to be influenced by a magnetic gradient field. The estimation algorithm is executed for transmission of estimated values for the status data of the magnetic resonance system. The estimated values specify a predicted change of the status data for a measurement sequence with the magnetic resonance system. The estimation algorithm uses an input variable and the at least one model parameter. Subsequently the estimated values are compared with measured values for the status data, wherein the measured values specify values for status data after the planned measurement sequence has been carried out. Depending on the result of the comparison, the at least one model parameter is adjusted.

### CROSS REFERENCE TO RELATED APPLICATIONS

This application claims the benefit of DE 10 2025 118 376.7 filed on May 13, 2025, which is hereby incorporated by reference in its entirety.

### FIELD

Embodiments relate to a computer-implemented method, computer program, computer-readable medium, data processing system, and magnetic resonance system for adjustment of at least one model parameter for an estimation algorithm for estimating status data of a magnetic resonance system.

### BACKGROUND

In a magnetic resonance system, such as for example a magnetic resonance tomography unit, gradient coils are employed to create a magnetic gradient field. This involves a secondary magnetic field that distorts a main magnetic field or basic magnetic field, which is created by a basic magnet, in a known pattern. The basic magnetic field is a strong constant magnetic field, usually in the range of a few tesla, which is created using superconductivity by using superconducting magnetic coils.

Through the distortion, a resonance frequency of atoms in a measurement object, with which its nuclear spins aligned by the basic magnetic field are excited into oscillation by having high-frequency radio wave pulses applied to them, varies depending on the position of the atoms in the measurement object. This provides a spatial encoding or spatial resolution via a respective origin of a response signal, which is produced on detection of the oscillations of the atoms by a receive coil.

During operation of the magnetic resonance system, the gradient coils are operated with radio-frequency electrical alternating current pulses in order to create the magnetic gradient field. This magnetic alternating current field may unwantedly influence the basic magnet. For example eddy currents are induced by stray fields in a housing structure for the basic magnet. The reason for this happening is that the housing structure may contain components or modules made of an electrically conductive or electromagnetically excitable material, such as for example aluminum or steel. Ohmic heat is created by the eddy currents, whereby the demand on a cooling system for cooling the basic magnet, for example its superconducting magnetic coils, increases. Depending on the cooling concept chosen, this input of heat may have various effects.

For so called wet magnet systems, in which the magnetic coils are cooled in a bath of liquid helium, heating leads to an increase in pressure in the container for the helium. When the pressure becomes too high, the result may be that the helium evaporates into the atmosphere. The result is a (local) increase in temperature. In the worst case the result may be an abrupt loss of the superconductivity of the magnet coils. This phenomenon is also referred to as quench or quenching.

For what are known as dry systems (“dry magnets”), in which the magnet coils are cooled by conductive cooling with a heat sink, heating leads to an increase in the temperature of the basic magnet. This increase in temperature may likewise lead to quenching when the cooling power of the system is no longer sufficient.

The input of heat may thus result in undesired system states of the magnetic resonance system, which restrict its functional capability and/or operation, for example may limit the performance of the system and thereby for example reduce the quality of imaging. There are various options for dealing with a corresponding input of heat.

For example EP 4 517 359 A1 discloses a shielding arrangement for a magnetic resonance device. In this case a shield structure as a double-walled hollow cylinder is used to accommodate a main magnet. In addition a shield tube is contained in the shield structure, which additionally shields the basic magnet.

EP 3 650 879 B1 discloses a method for monitoring an operating parameter for a magnetic resonance system. In this case the value of a vibration amplitude of a housing element of the magnetic resonance system is established for a vibration spectrum. Then, on the basis of a transmission function, as a function of the vibration spectrum established, the value of the operating parameter is determined, which may be a temperature, a pressure, an energy input or a variable dependent thereon, for example.

US 2022/0146607 A1 discloses a magnetic resonance imaging device for which a limiting imaging condition is determined based on imaging parameters. The limiting factor in this case is the maximum permitted input of heat into a superconducting magnet. The parameter is determined by an estimation function being applied before a measurement is carried out.

U.S. Pat. No. 10,444,313 B2 discloses a method for operating a magnetic resonance device. In this case a limiting factor is determined for magnetic resonance data, which is reflected as an interference frequency when recording the MR data. For this the behavior of the magnetic resonance device is estimated in a pre-calculated sequence. There are thus options for estimating the input of heat into the magnet before a measurement sequence is carried out and in response to which for example for informing an operator of the system about potentially critical protocols, before these are applied. These methods are limited however, as a result of inexact knowledge about the precise structure and the material properties of the components of the magnetic resonance system. Manufacturing tolerances and material properties may vary and have a significant influence on the system behavior. Moreover, further effects, such as for example loss of cooling system performance over the service life, for example due to the wear on the so-called cold head in the cooling system, are still not taken into consideration.

### BRIEF SUMMARY AND DESCRIPTION

The scope of the present disclosure is defined solely by the claims and is not affected to any degree by the statements within this summary. The present embodiments may obviate one or more of the drawbacks or limitations in the related art. Independent of the grammatical term usage, individuals with male, female or other gender identities are included within the term.

Embodiments improve an estimation algorithm for estimation of status data of a magnetic resonance system.

One aspect relates to a computer-implemented method for adjustment of at least one model parameter for an estimation algorithm for estimation of status data of a magnetic resonance system. The magnetic resonance system includes a basic magnet, which is arranged in a housing structure. In this arrangement, the basic magnet and/or the housing structure are able to be influenced by a magnetic gradient field, which is created for example by gradient coils. The influence may take place electromagnetically, for example, by eddy currents being induced and/or by mechanical oscillations in the acoustic frequency range or below it, which are created by the gradient fields in the metallic parts of the housing structure by magnetic forces. The method includes the following steps: First of all the estimation algorithm for establishing estimated values for the status data of the magnetic resonance system is estimated. The estimated values in this case specify a predicted change in the status data for a planned, i.e. an upcoming or subsequent measurement sequence with the magnetic resonance system. It is thus a matter of estimating or predicting the future behavior or the status of the magnetic resonance system during operation, even before the measurement sequence has been carried out. For determining the estimation variables, the estimation algorithm uses at least one input variable and at least one model parameter.

Subsequently, the estimated values are compared with measured values for the status data. The measured values specify values measured for the status data after the planned measurement sequence has been carried out. Thus, after the estimation algorithm has been executed, the measurement sequence may be carried out automatically. Subsequently, the estimated values are compared with the measured values, which are produced as the result of the measurement sequence. The measured values for example just deliver information about the actual status of the system. However, they do not allow conclusions about the long-term behavior of the status of the system after or during a planned measurement sequence. For this, an estimation in advance is needed. Specifically, it may occur that the system experiences performance difficulties in the middle of a measurement sequence, because for example the cooling system is no longer cooling sufficiently, which would corrupt the measurement results or make them unusable. The measurement quality is thus also made worse by this. In the worst case the result may even be quenching. It may then occur that the device is destroyed or its operation is at least interrupted over a long period.

Depending on the result of the comparison, finally the at least one model parameter is adjusted for the estimation algorithm. This means that the respective model parameter is changed, and indeed especially so that an error of the previous model parameter in the estimation that has been produced by comparison with the measured values is reduced or for example improved. For this a suitable method for error minimization is employed.

With the adjusted model parameter, the described method may be carried out once again for a further or subsequent measurement sequence. In this case, the respective updated or adjusted model parameter is used for the estimation algorithm. For example, the method is carried out continuously or repeatedly, for example for each upcoming measurement sequence. Naturally, the repetition rate of the method may also be adjusted or varied.

The result of the estimation algorithm may be output, for example by a control facility of the magnetic resonance system, to a user or an operator of the system. This may be an output or a warning for example that the planned measurement cycle cannot be carried out. It is also conceivable for the control facility to establish a changed measurement cycle, for example with other measurement parameters or operating parameters, for the operation of the magnetic resonance system and to output it as a suggestion to the user, of which the estimated value does not exceed a predetermined limit value. For example, a permission or confirmation of the user is required for changing the measurement cycle. It is likewise conceivable for the control facility to carry out the changed measurement cycle without intervention by the user. The output is purely by way of information. It is however also possible for the control facility to prevent the measurement cycle for which the estimated value exceeds the predetermined limit value from being carried out.

With the method the model parameter or parameters, with the aid of which the estimation algorithm undertakes the estimation of the system status, may be adjusted. Through this the estimation algorithm is optimized with each iteration of the method. Thus no tedious and expensive calibration measurements with long measurement times lasting several hours for correcting the model parameters are needed, as was previously the case. It is sufficient to carry out the calibration measurements for first determination of the calibration measurements of the model parameters once, for example after manufacturing or during configuration at the installation site. As an alternative, the calibration measurement may be carried out for a system type, which could also be implemented purely virtually, in order to define default model parameters, which are installed at the beginning for each system. During operation, the individual system may continually optimize itself better and adjust the model parameters to its status.

An iteratively adjusting algorithm is thus provided in order to adjust the estimation algorithm for each further or subsequent measurement sequence if need be. For example, the estimation algorithm is implemented as a machine learning model. The method thus involves a learning process or training process for learning the estimation algorithm. The method may thus be understood as a method for training a machine learning model. Thus, a learning algorithm for machine learning is involved.

The method also has the advantage that, for example with “dry systems”, the process may be especially sensitive to temperature increases. These have a lower thermal capacity than wet systems, for example. Therefore what are known as “hot spots” may occur at certain points, which may adversely affect operation. With the proposed estimation algorithm with adjustable model parameters, these hot spots may be recognized at an early stage and a critical input of heat of an upcoming measurement sequence avoided.

For the estimation algorithm, a known method from the prior art, for example from US 2022/0146607 A1 or U.S. Pat. No. 10,444,313 B2 may be used. A first or higher-order transfer function, which contains the model parameters as variables, is resolved for the estimation for example.

Status data means parameters that are set or are produced during operation of the magnetic resonance system for the respective measurement sequence. They depend for example on measurement parameters or operating parameters that are set for the respective measurement sequence. The status data may for example describe a temperature, a pressure, a resistance, an energy input, a vibration amplitude and/or a system variable dependent thereon. This involves parameters via which the heat input in the basic magnet and thus also potential unwanted system states may be deduced. The status data thus decides about whether the measurement quality or level is retained with the magnetic resonance system, or whether the measurements carried out in the respective measurement sequence, thus for example the resulting image data, are unusable or whether operation cannot be continued.

A model parameter may be understood as an inner variable of the estimation algorithm, which is used in order to optimize the result in the sense of a learning algorithm. A model parameter may for example be an optimization parameter (fitting parameter) for the estimation algorithm. This means for example that an abstract parameter is involved, which does not have a (direct) physical connection to the system.

As an alternative, for example, it involves a configuration variable, from which assumptions about the system or its behavior may be derived. For example the respective model parameter may be understood as a coefficient that influences the characteristics of the system (system characteristics). A model parameter is defined once for example by the calibration measurements of the system or by simulations. These measurements or simulations are complex and last a long time, so that a regular repetition over the run time is not cost effective. In ongoing operation the respective model parameter is therefore adjusted by the learning algorithm to the current system status. It therefore involves a changeable variable.

A model parameter in this context may be a time constant for example, which specifies how quickly the system heats up for a certain input of heat by operation of the gradient coils. A model parameter may, as an alternative or in addition for example, be a heating-up constant, which specifies how greatly the power introduced by the operation of the gradient coils is converted into increased temperature. In addition, or as an alternative, a model parameter may be a heating-up or time constant of various components or a coefficient for the variable cooling power of a so-called cold head, which where necessary is corrected at increased temperature. It is also conceivable for a model parameter to describe an attenuation or eigen frequency, for example when the estimation is realized by a second-order transfer function.

In an embodiment, the at least one model parameter is only adjusted when the measured values deviate by a predetermined deviation criterion from the estimated values. This means that a check is made in the comparison as to the order of magnitude by which measured values deviate from the estimated values. The size of the deviation, by which the respective model parameter is adjusted, is predetermined in this case by the deviation criterion. The deviation criterion may for example include a tolerance range for this. The tolerance range may specify a range of values for a maximum difference between the measured values and the estimated values. When the measured values and the estimated values in accordance with the comparison deviate from one another by more than the predetermined tolerance range the respective model parameter (value) is for example adjusted. Otherwise the respective previous model parameter (value) is for example retained, no adjustment takes place. For example the adjustment takes place when the measured values deviate by at least 1%, for example by at least 5%, for example by at least 10%, from the estimated values. For example, depending on the amount of the difference between the measured values and the estimated values there is a different reaction. For example, with small deviations (for example less than 5%) initially only a warning is output, while for larger deviations (for example 5% or more) the adjustment is made.

In an embodiment, the at least one input variable specifies an initial state of the magnetic resonance system and/or a measurement parameter for the planned measurement cycle.

The initial state, for example, means current measured values of the status data of the magnetic resonance system directly before the estimation for the upcoming measurement cycle. In addition, or as an alternative, the initial state may also relate to the basic state of the system. This means that measured values of the system at rest, i.e. when the system has been switched off for a predetermined time for example. For example, this may involve a basic temperature of the system, which for example occurs as a function of an ambient temperature and thus also depending on location in the basic state.

The measurement parameters mean the operating parameters or settings for the magnetic resonance system with which the system is operated in a respective measurement sequence, and which exert particular influence on the input of heat. The measurement parameters may for example be an input power, a frequency and/or a signal form, with which for example the gradient coils are operated. In addition, or as an alternative, a measurement parameter may for example be the number of slices, a slice thickness, and/or for example an area of the measurement object, i.e. for example a part of the body that is to be avoided, to give just a few further examples here.

In an embodiment, for each type of measurement sequence a repetition rate is defined for the execution of the method, depending on a difference between the at least one previous model parameter that has been used before the execution of the respective measurement sequence for the estimation algorithm, and the at least one adjusted model parameter, which is used after the execution of the measurement sequence for the estimation algorithm. Thus the ability to execute the method depending on the values of the measurement parameter before and after the adjustment is determined.

To put it differently, the repetition rate of a number of (different) measurement sequences is adjusted to the type of measurement sequence that is just to be used. In this case, various types of measurement sequences are able to be distinguished from one another by the measurement parameters and values of the measurement parameters. Depending on the value of the measurement parameters, the measurement sequences create a different state of the magnetic resonance system, i.e. for example different input of heat into the magnet coils. The system may recognize the various types of measurement sequence for example with the aid of the measurement parameters (measurement parameter values) or by a user specification made by an operator. For measurement sequences that are known to cause a higher input of heat, a lower repetition rate is for example defined than for measurement sequences that are known to cause a higher input of heat.

In order to define the repetition rate for each type of measurement sequence, a learning routine may be carried out. In the learning routine, for each type of measurement sequence carried out, a delta, i.e. the difference between the previous and the adjusted model parameters, is recorded or stored. When enough data points are collected, depending on the delta, the model parameter groups with measurement sequences are formed. For each group of measurement sequences, a frequency of execution may be defined accordingly. In their repetition rate, the groups therefore decide on the carrying out of the method. For example, measurement sequences that produce more input of heat are carried out less frequently than measurement sequences that produce a greater input of heat. In this way for example the repetition rate may be lowered, when the estimation function predicts a temperature that is too high for the magnet after the measurement sequence has been carried out. This applies for example for measurement sequences with specific status data, for example a higher start temperature of the magnet caused by preceding sequences. When the specific type of measurement sequence is now upcoming once again or is planned after the end of the learning routine, a decision may be made with the aid of the repetition rate as to whether the method, i.e. the estimation and adjustment of measurement parameters, is necessary or not, for example it may be assumed that the input of heat is low for this measurement sequence.

In an embodiment, depending on the at least one adjusted model parameter, for example its value, an ageing state, i.e. a degradation of the magnetic resonance system, is established. The repetition rate for the execution of respective measurement sequences of the method is then defined as a function of the ageing state.

This means that a deduction is made with the aid of the adjusted model parameter about the degradation of the magnetic resonance system. The ageing namely has an influence on the status data. For example the cooling power may deteriorate over time, because for example the cold head wears. When the same measurement sequence is carried out after a certain period of service life compared to the beginning of the service life, a higher net input of heat would thus be produced in the basic magnet.

In order to determine the ageing state, a change or difference between the adjusted model parameters and the original model parameter may be determined for example. The original model parameter means that parameter that has been measured or prespecified at the beginning of the service life, for example during a calibration measurement.

In an embodiment, in order to avoid unwanted system states, a recommendation and/or a specification for operating parameters of the magnetic resonance system, i.e. the measurement parameters of the magnetic resonance system for the planned or subsequent measurement sequence and/or pauses between a previous and a planned measurement sequence is output depending on the estimated values established.

Here and below, the pre-specification and/or recommendation is based on the result of the estimation algorithm. For example, the pre-specification and/or recommendation will be applied independently of how high, in accordance with the estimated values, the predicted input of heat into the system will be. The smaller the potential input of heat, the shorter for example the pauses may be kept. As an alternative, it is conceivable to change the measurement parameters for the upcoming measurement sequence or to select another type of measurement sequence, and to do it so that a higher input of heat is produced, provided the operation of the system allows this. Before carrying out the changed measurement sequence, in order to be sure, the estimation may be carried out once again.

This means that the system may recommend the use of specific measurement parameters for the subsequent measurement sequence. In addition, and/or as an alternative, the system may even restrict the measurement parameters by pre-specifying them. Furthermore the system may propose specific pauses between two consecutive measurement sequences or may actively implement these for example, by the magnetic resonance system switching itself off or being put into its idle state for example. This means that after the estimation algorithm has been executed, but before the planned measurement sequence is carried out, there is intervention into the system settings (measurement parameters).

The information may be output for example to a control facility or a control device that sets the measurement parameters for the desired measurement sequence. As an alternative, the output may be to an operator. This may be realized for example by a display on a screen of the magnetic resonance system. The display may for example restrict the suggestion with the settings or the possible settings for the operator, by for example limit values being set and thereby specific ranges not being able to be chosen for the measurement parameters. As an alternative it is conceivable to pre-specify corresponding default values for the settings via the screen or directly at the control facility, automatically for example, without giving the operator an option to choose them.

In an embodiment, to avoid unwanted system states, depending on estimated values established, i.e. after the estimation algorithm has been executed or before the planned measurement sequence is carried out, to output a recommendation for planning a series of different measurement sequences that are to be carried out one after the other.

This means that the MR system (magnetic resonance system) may establish an order of the individual measurement sequences in which the estimated value does not predict any critical system states. The result may be output for confirmation or be carried out immediately in this changed series of MR system. It is thus a matter of planning the order for various measurement sequences, which for example are due on measurement data. In this way for example, on recognition of a measurement sequence with potentially a high input of heat, it may be suggested that the system gives preference to another measurement sequence with potentially lower input of heat. The measurement sequence with the potentially higher input of heat may then for example be carried out at a later point in time.

In an embodiment the estimation algorithm contains an additional neural network. That means that the estimation algorithm may be implemented as a machine learning model (MLM), which is built on an artificial neural network (ANN). A measurement parameter may specify the linkage of the nodes.

Expressed in general terms, a trained MLM may emulate cognitive functions, which make a connection between human understanding. For example the MLM, by training based on training data, may be capable of adapting itself to new circumstances and of detecting patterns and extrapolating. Another term for a trained MLM is “trained function”.

In general the parameters of an MLM may be adjusted or updated by training. In such cases supervised training, semi-supervised training, unsupervised training, reinforcement learning) and/or active learning may be employed. Above and beyond this representation learning, which is also referred to as feature learning, may be used. For example the parameters of the MLM may be adjusted iteratively by a number of steps of training. For example during training of a specific loss function, which is also referred to as a cost function, may be minimized. During training of an artificial neural network (ANN), for example the back propagation algorithm may be used.

An MLM may include an ANN, a Support Vector machine, a decision tree and/or a Bayesian network, and/or the MLM may be based on k-means clustering, Q-learning, genetic algorithms and/or association rules. An ANN may be or may contain a deep neural network, a CNN (convolutional neural network) or a convolutional deep neural network. Moreover an ANN may be an adversarial network, a deep adversarial network and/or a GAN (generative adversarial network).

In accordance with a further aspect, embodiments relate to a computer program with commands. When the commands are executed by a data processing system, the commands cause the data processing system to carry out the computer-implemented method.

The commands may be present as program code, for example. The program code may for example be provided as binary code or Assembler and/or as source code of a programming language, for example C, and/or as program script, for example Python.

In accordance with a further aspect, embodiments relate to a computer-readable memory medium, for example a physical and/or non-volatile computer-readable memory medium, which stores a computer program.

The computer program and the computer-readable memory medium are each computer program products with the commands.

In accordance with a further aspect, embodiments relate to data processing system, which is configured to carry out the computer-implemented method.

Unless specified otherwise, all steps of the computer-implemented method are carried out by a data processing system that contains at least one data processing device. For example, the at least one data processing device is configured or adjusted to carry out the steps of the computer-implemented method. For this purpose, the at least one data processing device may store a computer program for example, which contains commands that, when they are executed by the at least one data processing device, cause the at least one data processing device to carry out the computer-implemented method. The computer-implemented method may also be implemented entirely or in part in hardware. The expressions “data processing system” and “at least one data processing device” may be used interchangeably here and below. This also applies to the corresponding terms derived therefrom.

For the case in which the at least one data processing device contains two or more data processing devices, specific steps of the steps carried out by the at least one data processing device may also be understood as different data processing devices carrying out different steps or different parts of a step. For example it is not necessary for each data processing device to carry out the steps. In other words the carrying out of the steps may be distributed between the two or more data processing devices.

In the present disclosure the terms “data processing system” and “at least one data processing device” may be used interchangeably. A data processing device may for example be understood as a data processing device that contains a processing circuit. The data processing device may thus for example process data for carrying out computing operations. Where necessary this also includes operations for carrying out indexed accesses to a data structure, for example an LUT (look-up table), and also a data processing process implemented in hardware.

The data processing device may for example contain one or more computers, one or more microcontrollers and/or one or more integrated circuits, for example one or more application-specific integrated circuits, ASIC, one or more field-programmable gate arrays, FPGA, and/or one or more systems on a chip, SoC. The data processing device may also contain one or more processors, for example one or more microprocessors, one or more central processing units, CPU, one or more graphics processing units, GPU, and/or one or more signal processors, for example one or more digital signal processors, DSP. The data processing device may also contain a physical or a virtual network of computers or other of the units.

In various embodiments, the data processing device includes one or more hardware and/or software interfaces and/or one or more memory units.

A memory unit may be configured as a volatile data memory, for example as dynamic random access memory, DRAM, or static random access memory, SRAM, or as non-volatile data memory, for example as read-only memory, ROM, as programmable read-only memory, PROM, as erasable programmable read-only memory, EPROM, as electrically erasable programmable read-only memory, EEPROM, as flash memory or flash EEPROM, as ferroelectric random access memory, FRAM, as magnetoresistive random access memory, MRAM, or as phase-change random access memory, PCRAM.

In accordance with a further aspect, a magnetic resonance system with a basic magnet and a housing structure in which the basic magnet is arranged is provided. The housing structure envelops or encloses the basic magnet, for example entirely. The basic magnet and/or the housing structure are able to be influenced at least by a magnetic gradient field, for example electromagnetically or by mechanical oscillations. The magnetic resonance system includes at least one gradient coil, which is arranged outside the housing structure, and is configured to create the gradient field. Furthermore, the magnetic resonance system includes a sensor facility for detection of measured values for status data, which specifies in accordance with the value for the status data after a planned measurement sequence has been carried out with the magnetic resonance system. Finally the magnetic resonance system also includes a data processing system. Thus, with the magnetic resonance system, by using the data processing system the computer-implemented method may be carried out.

In an embodiment, the sensor facility includes at least one sensor for detection of measured values, such as for example the temperature or oscillation of a part of the housing structure and/or of an attachment arrangement for the basic magnet in the housing structure. Thus, not only the state of the basic magnet but also the state of the individual parts of the housing or of other components that are employed in the magnetic resonance system may be determined. This provides the estimation and measurement to be undertaken highly accurately and dependent on the structure.

Further forms of the computer program, of the memory mediums, of the data processing system and magnetic resonance system follow on directly from the various embodiments of the method and vice versa. For example, individual features and a corresponding explanation as well as advantages with regard to the various forms of embodiment for the method are able to be transferred by analogy to corresponding forms of embodiment of the other aspects.

Above and in what follows, the solution is described both with regard to the claimed systems and also with regard to the claimed methods. Features, advantages or alternative forms of embodiment may be assigned to the other claimed subject matter and vice versa. In other words, the claims and forms of embodiment for the systems may be improved by features that are described or claimed in conjunction with the respective methods. In this case, the functional features of the method are implemented by physical units of the systems.

Further features and combinations of features emerge from the figures and the description as well as from the claims. For example, further forms of embodiment do not absolutely have to contain all features of one of the claims. Further forms of embodiment may have features or combinations of features that are not given in the claims.

Embodiments are explained in greater detail below with the aid of specific embodiments and associated schematic drawings. In the figures the same elements or elements that have the same functions may be labeled with the same reference characters. The description of elements that are the same or have the same functions may possibly not necessarily be repeated with regard to different figures.

### BRIEF DESCRIPTION OF THE FIGURES

FIG. 1 depicts a schematic diagram of a magnetic resonance system according to an embodiment.

FIG. 2 depicts a schematic flow diagram for a method for adjustment of at least one configuration variable for an estimation algorithm for estimating status data of the magnetic resonance system according to an embodiment.

### DETAILED DESCRIPTION

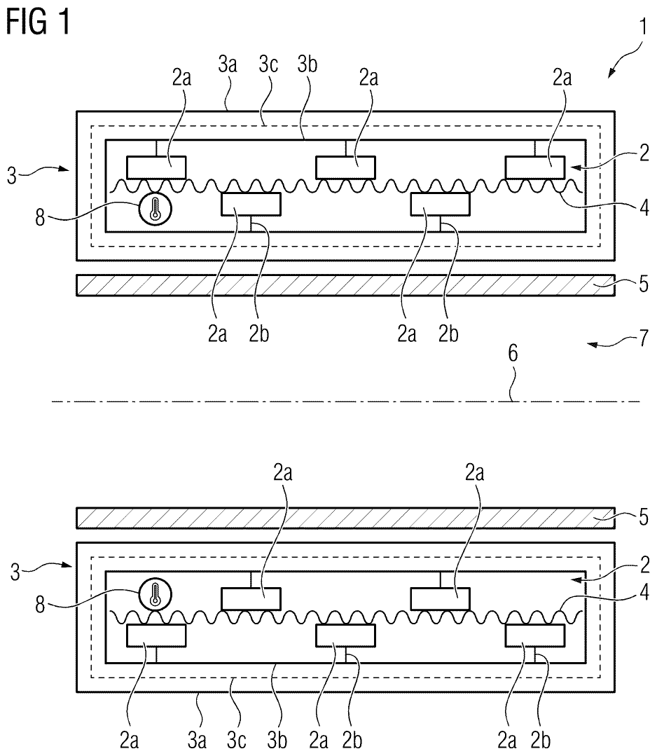

FIG. 1 depicts a schematic diagram of a cross section through a magnetic resonance system 1. The magnetic resonance system 1 takes the form of a cylinder i.e. a ring-shaped structure, which extends about an axis of rotational symmetry 6. Located in the area of the axis of rotational symmetry 6 is an image recording region 7, into which a measurement object, such as for example a patient, may be introduced for creating an image.

The magnetic resonance system 1 includes a basic magnet 2, which is arranged in the shape of a ring in a housing structure 3. The basic magnet 2 includes superconducting magnet coils 2a. The superconducting magnet coils 2a are for example made of a superconducting material mix, such as for example copper with superconducting filaments. The magnet coils 2a are attached by attachment elements 2b of an attachment arrangement, which in the present case for example is shown as suspension bars, attached to the housing structure 3.

The housing structure 3 encloses the basic magnet 2, for example entirely. The basic magnet 2 is arranged, in this embodiment, in a measurement system in an inner housing 3b of the housing structure 3. In a wet system the inner housing 3b may be configured as the cryogen, i.e. a coolant, such as for example liquid helium, for cooling the basic magnet 2. For this purpose, several hundred liters of the cryogen are held in the inner housing 3b. As an alternative to wet systems, there are also so-called dry systems, as is shown for example in FIG. 1, in which the cooling is essentially brought about by a heat conductor 4 or a heat sink for conductive cooling. To this end, the magnet coils 2a are brought into contact with a conductive thermal conductor 4, which includes aluminum for example. This likewise conducts the heat for example via a cryogenic circuit (not shown in FIG. 1) away from the magnetic coils 2a. Here, however, significantly less cryogen, such as for example helium, for example in the range of less than 1 L, is used. In a dry system, the helium is merely used in the cooling apparatus, the pulse tube cooler, in order to generate the cryogenic temperatures. Otherwise the heat is dissipated by thermal conduction in the solid bodies, i.e. the thermal conductor 4 here, and in addition or as an alternative the superconducting coils themselves and/or the attachment elements 2b.

Through the cryogen or the heat conductor 4, it is ensured that the temperature of the magnetic coils 2a is kept in the cryogenic range (usually around 4K), so that the desired superconducting characteristics are obtained. The cryogen is introduced for example by cryostat (not shown in FIG. 1) by a coolant circuit into the inner housing 3b.

The inner housing 3b is surrounded by a further structure, called an outer housing 3a here. As a rule a vacuum is produced between the outer housing 3a and the inner housing 3b. The outer housing 3a is therefore also referred to as the outer vacuum chamber.

The outer and inner housing 3a, 3b are for example made of an electrically conductive material, which includes copper or aluminum for example. Naturally, other materials with a high electrical conductivity and/or high thermal conductivity may be included or used for the manufacturing of the housing structure 3.

A so-called cold shield or cryoshield 3c may also be located between the outer housing 3a and the inner housing 3b. The cryoshield 3c has the function of reducing thermal radiation between the outer and the inner housing 3a, 3b. Moreover, it is used for electromagnetic shielding of the basic magnet 2 from electromagnetic stray fields.

At least one gradient coil 5 is moreover located outside the housing structure 3, for example in the direction of the axis of rotational symmetry 6. For example a magnetic resonance system 1 includes a number, for example three, gradient coils, which are each used for one spatial direction (x-y-z). The respective gradient coil 5 is inserted in the interior of the basic magnet 2 concentrically. An attachment of the gradient coil 5 to the housing structure 3 is not shown for reasons of clarity.

The magnetic resonance system 1 may also include further components that magnetic resonance systems usually have. For example a controller for the basic magnet 2 and the gradient coils 5 or a receive device or an imaging device is not shown in FIG. 1 for reasons of clarity. The basic structure and operation of a magnetic resonance system is known per se, which is why a more detailed description will not be provided here.

During operation, the basic magnet 2 now generates a constant magnetic field (basic magnetic field) in the range of a plural number of tesla (usually 1.5 T to 3 T) for the imaging of the measurement object. An alignment of the nuclear spins of atoms in the measurement object is achieved by this.

By a radio wave pulse generator (not shown in FIG. 1), high-frequency radio wave pulses are sent out to the measurement object. Through this, the ordered or aligned nuclear spins are excited to an oscillation in their resonance frequency. This oscillation may be received as a radio-frequency response signal by a receive device (not shown in FIG. 1).

In addition, the gradient coils 5 are operated with an alternating current and thereby produce magnetic alternating fields, which influence the resonant spin frequency of the nuclear spins of the atoms in the measurement object. Through this, the response signal is resolved spatially, since only in this way may information about the location of the origin of the response signal be obtained for the image reconstruction. The gradient fields are thus additional magnetic fields to the static magnetic field, which for example are used in three spatial directions (x-y-z) for the spatial resolution. The gradient fields are small by comparison with the basic magnetic field.

During operation of the gradient coils 5, magnetic stray fields may now arise, which may propagate in the basic magnet 2 and/or the housing structure 3 and may be responsible for the basic magnet 2 heating up. The input of heat is in this case for example dependent on the frequency with which the gradient fields are created. Eddy currents may namely be induced in the electrically conductive structures by the stray fields, for example the components of the housing structure. These eddy currents are converted into ohmic heat, which in its turn leads to heating up and in the worst case may lead to evaporation of the cryogen 4. The heating up may lead to deterioration of the image quality during imaging or may result in complete outage or failure of the magnetic resonance systems 1 through a so-called quench (loss of the superconductivity).

An increased heating up is thus an unwanted system state of the magnetic resonance system 1, which is to be avoided. This heating up or the resulting amount of heat may be measured for example with a sensor facility 8, as is shown for example in FIG. 1. To this end, the sensor facility 8 includes one or more sensors with which measured values may be captured for status data Z during operation of the magnetic resonance system 1. For example, the sensor facility 8 includes one or more sensors in each case for example for each electromagnetically excitable and thus heatable structure, such as for example the components or elements of the housing structure 3, the attachment elements 2 and the magnet coils 2a. This provides all components of the magnetic resonance system 1 to be monitored with regard to their heat.

With the sensor system it is possible, for example, to measure a temperature, a pressure, an electrical resistance, an input of energy, a vibration frequency or amplitude and/or another corresponding variable which delivers feedback about the heating up of the magnetic resonance system 1. The measured values M of the status data Z thus deliver as information an input of heat into the system.

In order to avoid unwanted system states, there are methods for estimating the temperature behavior of the magnet structure, for example of the basic magnet 2, in a magnetic resonance system, and of informing a user of the system about potentially critical measurement protocols or measurement sequences before these are carried out with the magnetic resonance system 1.

An example of such an estimation is known from US 2022/0146607 A1. In this disclosure, however, it is assumed that the input of heat and the cooling power are defined for each system and are not able to be changed. The values for this are based on a heating spectrum that is measured once, either for each system type, for example during manufacturing, or for each system individually during installation at the intended site. This essentially involves a calibration measurement, which usually requires long measurement times lasting several hours in order to deliver accurate information about the input of heat. Through this, long-term effects on the magnetic resonance system 1 remain unconsidered, or complex recalibrations are necessary. Moreover, variations in the material properties are not also taken into account. Losses in the cooling power system over its service life, such as for example a cold head degradation, are also not taken into account.

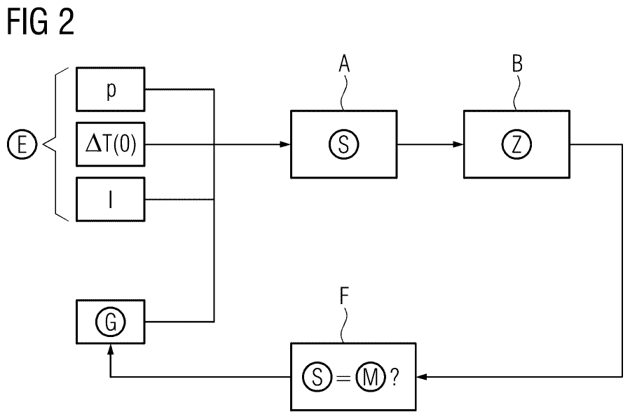

With dry systems for example, a precise temperature monitoring is of importance, since here so-called hot spots, i.e. regions with critical point temperatures, which cannot be detected by a sensor may form directly through input of heat and therefore must be learnt and predicted by an “intelligent” estimation function. In this application a self-learning algorithm is therefore proposed, with which, in an intelligent way, model parameters G of an estimation algorithm A may be adjusted, which take into account the heating up or cooling behavior of the magnetic resonance system 1 with and/or without operation of the gradient coils 5. By adjustment of the model parameters G, which may also be referred to a optimization parameters or configuration variables, the estimation algorithm A may be optimized or adjusted during ongoing operation of the magnetic resonance system 1, so that the assumptions for the input of heat into the system are always kept up-to-date. The proposed algorithm may for example be executed by a data processing system of the magnetic resonance system 1. FIG. 2 depicts an example of a flow diagram of the method for a computer-implemented method for adjusting the at least one model parameter G or an estimation algorithm A for estimation of status data Z of a magnetic resonance system 1, as is shown by way of example in FIG. 1.

In this case the method, as is shown in FIG. 2, depicts the estimation algorithm A with which estimated values S for the status data Z of the magnetic resonance system 1 during operation may be established. The estimated values S in this case specify a predicted change of the status data Z for a planned, i.e. an upcoming or subsequent, measurement sequence B with the magnetic resonance system 1. Thus the future behavior or the status of the magnetic resonance system 1 during operation is estimated or predicted. The estimated value S thus delivers information about the effect of a potential input of heat on the system, when the magnetic resonance system 1 is operated with a specific protocol, i.e. the desired measurement sequence B. The estimated values may be output for example in the form of a temperature or a pressure.

For establishing the estimated values S, the estimation algorithm uses at least one input variable E and at least one model parameter G. The respective input variable E specifies an initial state of the magnetic resonance system and/or a measurement parameter for the planned measurement cycle B. This for example also includes information about operating parameters or measurement parameters of the magnetic resonance system 1, which will be used for the measurement sequence B in the magnetic resonance system 1. This includes for example an input power p, which for example depends on the frequency at which the gradient coils 5 will be operated. The respective model parameter G describes a variable parameter, which includes the estimation algorithm A for the estimation. This thus involves coefficients that influence the result of the algorithm and that are able to be changed in order to improve the prediction for critical temperatures in the system.

If the estimation algorithm A delivers as its result that the estimated values S are not in order, i.e. there is likely to be overheating, then a specification or a recommendation for the planned measurement sequence B may be output. For example, a recommendation or specification for the measurement parameters of the magnetic resonance systems 1 for the planned measurement sequence B and/or pause time between a previous and the planned measurement sequence B is output to a user. As an alternative, it is conceivable, depending on the estimated values S, to output a recommendation for planning a series of different measurement sequences, which for example are planned for a measurement day or also have influence on the adjustment of measurement parameters, which for example have influence on the operating frequency of the gradient coils. This provides unwanted system states, i.e. overheating and for example quenching, to be effectively avoided. It is also conceivable to switch off the system for estimating a specific cooling down time.

If the result delivered by the estimation algorithm A is that the estimated values S are in order, i.e. no overheating is occurring, the measurement sequence B is carried out according to the estimation algorithm A. To this end the magnetic resonance system 1 is operated with the desired measurement parameters or system settings. After the measurement sequence B has been carried out, specific status data Z of the magnetic resonance system 1 is produced. This means that the system has for example heated up to a specific temperature. This status data Z may be measured by the sensor facility 8.

Now, in the method in accordance with FIG. 2 in feedback, i.e. in a feedback loop F, the estimated values S are compared with measured values M for the status data Z. Then a check is made for example as to whether the estimated values S and the actual resulting measured values M lie in a predetermined tolerance range in relation to one another. The tolerance range for example specifies a range of values for a maximum difference between the values by which these may deviate from one another at most. It is thus checked whether the estimation matches the actual results after the measurement.

Depending on the result of the comparison, the respective model parameter G is adjusted. For example, the adjustment is only undertaken when the measured values M deviate by the predetermined tolerance range from the estimated values S. The subsequent execution of the estimation algorithm A is then carried out with adjusted model parameters (model parameter values) G. Thus the model parameters G may where necessary be repeatedly adjusted in the ongoing operation of the magnetic resonance system 1.

The estimation algorithm A is for example implemented as a machine learning model. For example the estimation algorithm A may contain an artificial neural network. The method may thus involve a learning or training process for training the estimation algorithm A.

An example for the characterization of the individual components of the magnetic resonance system 1 with the estimation algorithm A may be realized by a so-called transfer function (TF) or transmission function. In the following example, an especially simple way of dealing with a first-order transfer function is described. Naturally, however, a higher-order transfer function or another option for establishing the estimated values S, as is known per se, may be used. In the following calculation example the temperature is described as an example for status data Z of the magnet coils 2a of a dry system. Naturally, in addition or as an alternative however, any other given item of the status data Z, such as for example the pressure or resistance, may be used.

The first-order transfer function for the thermal behavior of the magnet coils 2a may be assumed as:

$$H ( s ) = \frac{K}{τ s + 1}$$

The temperature T (t) is then calculated from:

$$T ( t ) = pK ( 1 - {e}^{- \frac{t}{τ}} ) + Δ T ( 0 ) {e}^{- \frac{t}{τ}} + T b$$

In this equation p is the input power, which for example is dependent on the frequency at which the gradient coils 5 are operated. K and τ in this embodiment are the model parameters G. K describes the input of heat into the magnetic resonance system 1. This means that K describes how much of the introduced power is converted into temperature or heat. τ is a time constant that describes how the magnetic resonance system 1 heats up with a certain power. ΔT(0) and Tb are examples of an initial state of the magnetic resonance system 1. A current temperature value of the basic magnet 2 before the estimation for the upcoming measurement cycle B is involved in this case. ΔT(0) thus specifies how warm the basic magnet or the other structures are before the respective method is carried out. Tb describes the basic temperature of the basic magnet 2. It involves the temperature that the system has in the basic state, i.e. when it is idle. It is for example dependent on the ambient temperature and is thus location-dependent. s is the so-called Laplace transform variable and describes a complex frequency.

With the transmission function shown, the focus is placed for example on the input of heat into the magnet coils 2a. Naturally, however, a function may also be set up with which the heat inputs that lead to the other structures and components of the magnetic resonance system 1 are used.

The estimation value S estimated in this way, thus the temperature T (t) over time here, may be compared with the current or measured temperature as measured value M or to another comparable parameter, such as for example the pressure or other status data, with which the temperature may be deduced, after the measurement sequence B has been executed. Subsequently, if need be, the coefficients of the transfer function, i.e. the model parameter G (thus in the present case the K and t), are adjusted.

The adjustment may be carried out for example by any given algorithm, which reduces or minimizes the errors between the estimated value S and the measured value M when using the corresponding model parameter G. A minimization problem is thus solved. The recursive least square method (RLS algorithm), the iteratively reweighted least square method or the reweighted least square method are suitable for this, to give just a few examples here.

With this approach, each execution of a measurement sequence B may be used to optimize the model parameters G, which characterize the basic magnet 2 and thereby to improve the accuracy of the prediction and take account of long-term changes of the magnetic resonance system 1.

It may even be possible to use the model parameters G in order to monitor the state of the basic magnet 2 for reaching specific limit values, these may namely be an early indication that the magnetic resonance system 1 has experienced performance issues or has a malfunction or is about to encounter one, whereby proactive maintenance may be proposed.

Moreover it is conceivable with this approach to identify system states or status data Z of measurement sequences B that, over time, produce high temperatures, i.e. a high input of heat into the basic magnet 2. It is then possible to use the described method only for specific groups of measurement sequences B or protocols. A repetition rate for carrying out the method may thus be adjusted. Moreover it is possible in this way to use the described method only in specific circumstances that are produced by the state of the basic magnet 2, for example when the performance of the cooling system degrades. Expressed differently, the ageing state of the system may be taken into consideration in order to adjust the repetition rate of the method for specific measurement sequences B. The user could also be informed here about the degradation of the magnetic resonance system 1 and thereby decide to only apply to a limited extent measurement sequences B that have a high input of heat. The energy efficiency of the magnetic resonance system 1 could be improved by this by low cooling power being needed by the cooling system. The magnetic resonance system 1 could thus be operated in an eco mode (economy mode).

Overall, with the method described, parameters, i.e. the model parameters G, may be determined individually for each system and adjusted automatically over its lifetime. Through this the estimation accuracy is improved, which allows the user of such a system to make informed decisions about the choice of measurement sequences B and of their measurement parameters. The resulting estimation is less conservative and allows the user actually to utilize the system up to its limits by overheating, than when prefabricated parameters are used by comparison with the adjusted model parameters G. Moreover, with the method used, temperature-dependent influences of various components on the sensitivity of the magnet coils 2 or the gradient stray fields may be taken into account.

The embodiments described herein teach a self-learning estimation for states of a basic magnet 2 of a magnetic resonance system 1.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that the dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for adjustment of at least one model parameter for an estimation algorithm for estimation of status data of a magnetic resonance system with a basic magnet that is arranged in a housing structure, wherein the basic magnet, the housing structure, or the basic magnet and the housing structure are configured to be influenced by a magnetic gradient field, the method comprising:
executing the estimation algorithm for establishing estimated values for the status data of the magnetic resonance system, wherein the estimated values specify a predicted change of the status data for a planned measurement sequence with the magnetic resonance system, wherein, for establishing the estimated values, the estimation algorithm uses at least one input variable and the at least one model parameter;
comparing the estimated values with measured values for the status data that specify measured values for the status data after the planned measurement sequence has been carried out; and
adjusting the at least one model parameter depending on a result of the comparison.

2. The computer-implemented method of claim 1, wherein the at least one model parameter is only adjusted when the measured values deviate from the estimated values in accordance with a predetermined deviation criterion.

3. The computer-implemented method of claim 1, wherein the at least one input variable specifies an initial state of the magnetic resonance system or of a measurement parameter for a planned measurement cycle.

4. The computer-implemented method of claim 1, wherein, for each type of measurement sequence, a repetition rate for the carrying out of measurement sequences of the method is defined as a function of a difference between at least one previous model parameter, which was used before the measurement sequence was carried out for the estimation algorithm, and the at least one adjusted model parameter, which is used after the measurement sequence is carried out for the estimation algorithm.

5. The computer-implemented method of claim 1, wherein, depending on the at least one adjusted model parameter, an ageing state of the magnetic resonance system is established and a repetition rate for the carrying out of measurement sequences of the method is defined as a function of the ageing state.

6. The computer-implemented method of claim 1, wherein, to avoid unwanted system states, depending on the established estimated values, a recommendation, a specification, or the recommendation and the specification for measurement parameters of the magnetic resonance system for the planned measurement sequence or pause times between a previous and the planned measurement sequences is output.

7. The computer-implemented method of claim 1, wherein to avoid unwanted system states, depending on the estimated values established, a recommendation for planning of a series of different measurement sequences that are to be carried out after one another is output.

8. The computer-implemented method of claim 1, wherein the estimation algorithm contains an artificial neural network.

9. A non-transitory computer implemented storage medium, including machine-readable instructions stored therein for adjustment of at least one model parameter for an estimation algorithm for estimation of status data of a magnetic resonance system with a basic magnet that is arranged in a housing structure, wherein the basic magnet, the housing structure, or the basic magnet and the housing structure are configured to be influenced by a magnetic gradient field, the machine-readable instructions when executed by at least one processor, cause the processor to:
execute the estimation algorithm for establishing estimated values for the status data of the magnetic resonance system, wherein the estimated values specify a predicted change of the status data for a planned measurement sequence with the magnetic resonance system, wherein, for establishing the estimated values, the estimation algorithm uses at least one input variable and the at least one model parameter;
compare the estimated values with measured values for the status data that specify measured values for the status data after the planned measurement sequence has been carried out; and
adjust the at least one model parameter depending on a result of the comparison.

10. A magnetic resonance system comprising:
a basic magnet;
a housing structure in which the basic magnet is arranged, wherein the basic magnet, the housing structure, or the basic magnet and the housing structure are configure to be influenced by a magnetic gradient field;
at least one gradient coil that is arranged outside of the housing structure and is configured to create the magnetic gradient field;
a sensor facility configured for detection of measured values for status data that specifies measured values for the status data after a planned measurement sequence has been carried out with the magnetic resonance system; and
a data processing system comprising at least one processor and a memory, the data processing system configured to:
execute an estimation algorithm for establishing estimated values for the status data of the magnetic resonance system, wherein the estimated values specify a predicted change of the status data for a planned measurement sequence with the magnetic resonance system, wherein, for establishing the estimated values, the estimation algorithm uses at least one input variable and at least one model parameter;
compare the estimated values with measured values for the status data that specify measured values for the status data after the planned measurement sequence has been carried out; and
adjust the at least one model parameter depending on a result of the comparison.

11. The magnetic resonance system of claim 10, wherein the sensor facility comprises at least one sensor for detection of measured values of a part of a housing of the housing structure and/or of an attachment arrangement for the basic magnet in the housing structure.

12. The magnetic resonance system of claim 10, wherein the at least one model parameter is only adjusted when the measured values deviate from the estimated values in accordance with a predetermined deviation criterion.

13. The magnetic resonance system of claim 10, wherein the at least one input variable specifies an initial state of the magnetic resonance system or of a measurement parameter for a planned measurement cycle.

14. The magnetic resonance system of claim 10, wherein, for each type of measurement sequence, a repetition rate for the carrying out of measurement sequences is defined as a function of a difference between at least one previous model parameter, which was used before the measurement sequence was carried out for the estimation algorithm, and the at least one adjusted model parameter, which is used after the measurement sequence is carried out for the estimation algorithm.

15. The magnetic resonance system of claim 10, wherein, depending on the at least one adjusted model parameter, an ageing state of the magnetic resonance system is established and a repetition rate for the carrying out of measurement sequences is defined as a function of the ageing state.

16. The magnetic resonance system of claim 10, wherein, to avoid unwanted system states, depending on the established estimated values, a recommendation, a specification, or the recommendation and the specification for measurement parameters of the magnetic resonance system for the planned measurement sequence or pause times between a previous and the planned measurement sequences is output.

17. The magnetic resonance system of claim 10, wherein to avoid unwanted system states, depending on the estimated values established, a recommendation for planning of a series of different measurement sequences that are to be carried out after one another is output.

18. The magnetic resonance system of claim 10, wherein the estimation algorithm contains an artificial neural network.
